(19) United States
(12) Patent Application Publication
(10) Pub. No.: US 2016/0181127 A1
(43) Pub. Date: Jun. 23, 2016

(54) METHOD FOR COUPLING CIRCUIT ELEMENT AND PACKAGE STRUCTURE

(71) Applicant: UNITED MICROELECTRONICS CORPORATION, HSINCHU (TW)

(72) Inventor: PO-CHEN KUO, Tainan City (TW)

(21) Appl. No.: 14/578,517

(22) Filed: Dec. 22, 2014

(51) Int. Cl. H01L 21/56; H01L 23/31; H01L 23/498

(52) U.S. Cl. CPC H01L 21/563; H01L 23/49816; H01L 23/49827; H01L 23/49838; H01L 23/3178

(57) ABSTRACT

A method for coupling an circuit element onto a carrier element includes steps of providing the circuit element having a front side, a back side, and at least a sidewall formed between the front side and the back side, wherein the sidewall has a sloped portion inclined to the front side at an angle greater than zero degree; bring the circuit element on the carrier element with the front side facing the carrier element; and forming an underfilling structure so that the underfilling structure is disposed on the carrier element and below the circuit element, and covers at least a portion of the sidewall. A package structure constructed by the above-mentioned method is also provided.

### FIELD OF THE INVENTION

The present invention relates to circuit element coupling method and structure, and more particularly to a package for a circuit element, such as a flip chip, with underfill process.

### BACKGROUND OF THE INVENTION

A conventional circuit element, such as a flip chip, usually has vertical sidewalls. As shown in FIG. 1, a flip chip 2 with a plurality of bumps 3 is coupled to a substrate 1 with an underfill 4. The flip chip 2 has a sidewall 21. However, during the underfilling process, the fillet may exceed the sidewall 21 to the top of the flip chip 2, or, an over-sized fillet may induce a cracking of the sidewall 21 of the flip chip 2.

### SUMMARY OF THE INVENTION

A purpose of the present invention is to solve the above-mentioned problems.

A method for coupling a circuit element onto a carrier element is provided. The method includes steps of providing the circuit element having a front side, a back side, and at least a sidewall formed between the front side and the back side, wherein the sidewall has a sloped portion inclined to the front side at an angle greater than zero degree; bringing the circuit element on the carrier element with the front side facing the carrier element; and forming an underfilling structure so that the underfilling structure is disposed between the circuit element and the carrier element and covers at least a portion of the sidewall.

The circuit element may be an integrated circuit chip, and the carrier element is a substrate or an interposer.

The sloped portion of the sidewall is formed by cutting a conventional circuit element from the back side to the sidewall, so that at least a portion of the sidewall is removed.

In an embodiment, the sidewall has a sloped portion at an angle greater than 30 degree.

The sloped portion of the sidewall may be formed by a bevel cutting process, a laser cutting process, a polishing process, a plasma cutting process, a waterjet cutting process, etc.

The present invention further provides a package structure. The package structure includes a circuit element having a front side, a back side, and at least a sidewall formed between the front side and the back side; a carrier element attached thereon the circuit element, wherein the front side of the circuit element faces the carrier element; and an underfill structure disposed between the circuit element and the carrier element, wherein the circuit element is surrounded by the underfill structure on at least a portion of the sidewall, and the sidewall includes a sloped portion inclined at an angle greater than zero degree.

In embodiments, the circuit element is an integrated circuit chip, and the carrier element is a substrate or an interposer. In other embodiment, the circuit element and the carrier element are connected through at least a through silicon via.

The sloped portion of the sidewall is inclined from a point nearing or located at the front side toward the back side. In an embodiment, the sloped portion is inclined at an angle greater than 30 degree.

The circuit element further includes a plurality of bumps disposed on the front side. The bumps may be solder balls, copper pillars with solders, etc.

### BRIEF DESCRIPTION OF THE DRAWINGS

The present invention will become more readily apparent to those ordinarily skilled in the art after reviewing the following detailed description and accompanying drawings, in which:

FIG. 1 is a schematic representation of a conventional flip chip package with underfill therein.

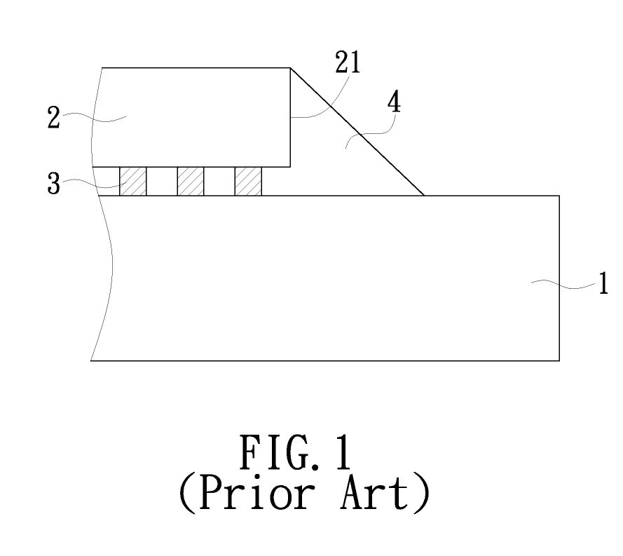

FIG. 2 is a cross-sectional view of a package structure according to an embodiment of the invention.

FIG. 3 is a cross-sectional view of a package structure with different underfilling situation according to another embodiment of the invention.

FIG. 4 is a cross-sectional view of a package structure with different sidewall inclining situation.

FIG. 5 is a cross-sectional view of a package structure with a copper pillar bump therein.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

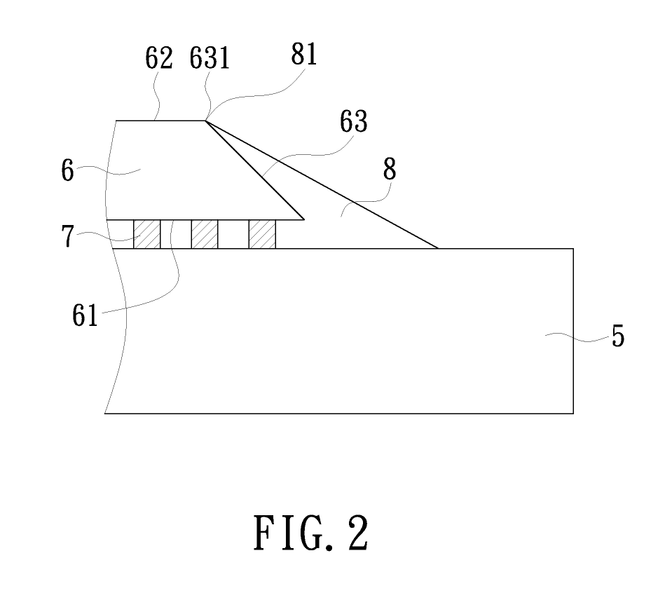

Referring to FIG. 2, a package structure includes a carrier element 5, a circuit element 6, and an underfill structure 8. The circuit element 6 has a front side 61, a back side 62, and a plurality of sidewalls 63 formed between the front side 61 and the back side 62. The circuit element 6 is connected to the carrier element 5 through a plurality of bumps 7 disposed on the front side 61 of the circuit element 6. The bumps 7 may be solder balls, copper pillars with solders, etc. In some cases, there might be some dummy bumps among the bumps 7 for a better underfilling effect. The front side 61 of the circuit element 6 faces the carrier element 5. The underfill structure 8 is disposed below the circuit element 6 and on the carrier element 5. The sidewall 63 of the circuit element 6 is inclined to the front side 61 thereof at an angle greater than zero degree. In other embodiment, the inclined angle is greater than 30 degree. The circuit element 6 may be an integrated circuit chip, and the carrier element 5 may be a substrate or an interposer. In other cases, the circuit element and the carrier element are connected through at least a through silicon via (not shown).

The method for coupling the circuit element 6 onto the carrier element 5 includes steps of providing the circuit element 6 having the inclined sidewall 63; bringing the circuit element 6 on the carrier element 5 with the front side 61 of the circuit element 6 facing the carrier element 5; and forming an underfilling structure 8 so that the underfilling structure 8 is disposed between the circuit element 6 and the carrier element 5 and covers at least a portion of the sidewall 63 of the circuit element 6. In some cases, the circuit element 6, e.g. an integrated circuit chip, may be treated by plasma before the underfilling process.

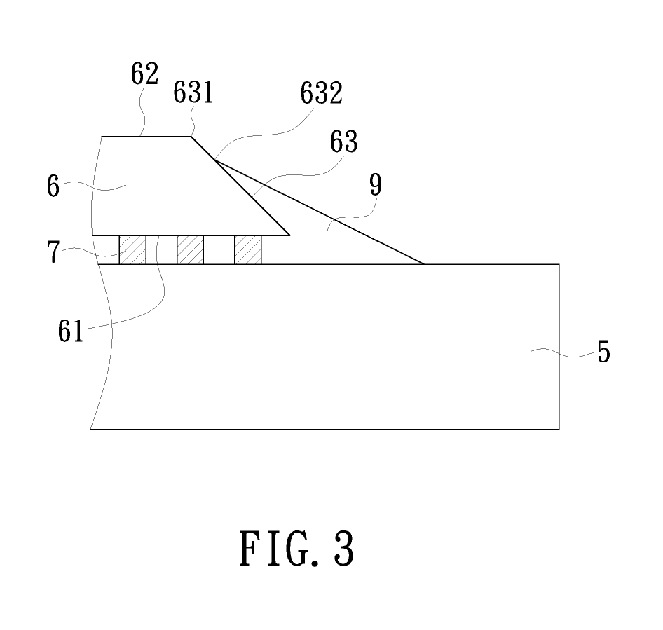

The inclined sidewall 63 may prevent the underfilling structure 8 exceeds a top point 631 of the sidewall 63. Accordingly, the sidewall stress is reduced and thus reduces the possibility of sidewall cracking. In another embodiment, as shown in FIG. 3, an underfilling structure 9 only covers the portion of the sidewall 63 lower than a point 632 of the sidewall 63 below the top point 631 thereof. The height of the underfilling structure 9 on the sidewall 63 may be controlled by varying factors such as the viscosity or amount of the fillet forming the underfilling structure 9, or the inclined angle of the sidewall 63.

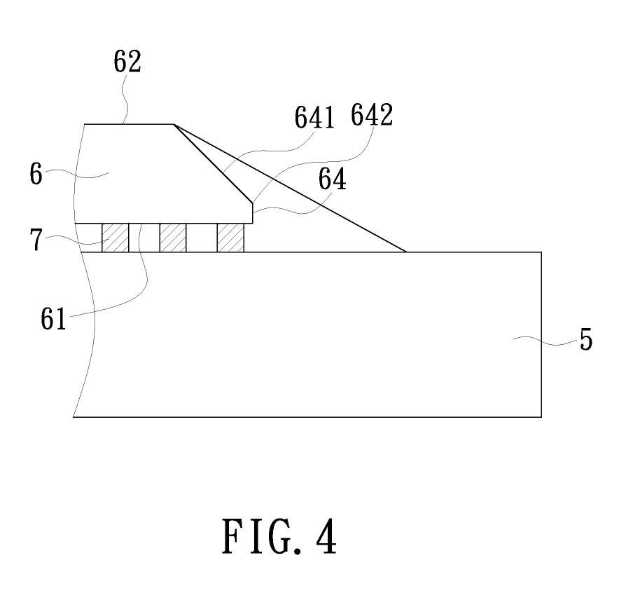

In fact, it is not necessary to incline the whole sidewall. As shown in FIG. 4, a sidewall 64 includes a sloped portion 641 inclined from a point 642 located below a lower portion of the sidewall 64, which is adjacent to the front side 61 of the circuit element 6, toward the back side 62.

The sloped portion 641 of the sidewall 64, or the inclined sidewall 63, may be formed by removing at least a portion of a vertical sidewall of a conventional circuit element by a bevel cutting process, a laser cutting process, a polishing process, a plasma cutting process, a waterjet cutting process, etc.

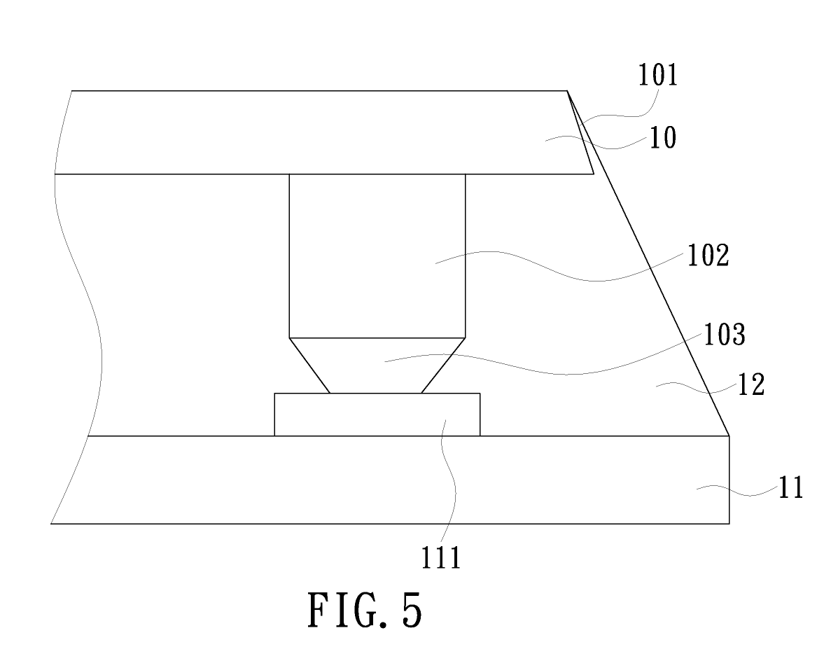

As shown in FIG. 5, the present invention can also be applied to the coupling of two chips 10, 11 connected by a copper pillar 102. The copper pillar 102 extended from the chip 10 is connected with the chip 11 having a pad 111 through a solder 103 between the copper pillar 102 and the pad 111. In this case, a sidewall 101 of the chip 10 is inclined for a better underfilling effect of an underfilling structure 12.

To sum up, the inclined portion of the sidewall of a circuit element will change the shape of the underfilling structure and reduce the stress of the warpage to the circuit element, which will thus reduce the possibility of sidewall crack. Furthermore, since the sloped portion is inclined from the front side to the back side of the circuit element, the area of the front side for forming the active elements of the circuit will not be reduced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A method for coupling a circuit element onto a carrier element, comprising steps of:
providing the circuit element having a front side, a back side, and at least a sidewall formed between the front side and the back side, wherein the sidewall has a sloped portion inclined to the front side at an angle greater than zero degree;
bringing the circuit element on the carrier element with the front side facing the carrier element; and
forming an underfilling structure so that the underfilling structure is disposed on the carrier element and under the circuit element, and covers at least a portion of the sidewall.

2. The method according to claim 1, wherein the circuit element is an integrated circuit chip, and the carrier element is a substrate.

3. The method according to claim 1, wherein the circuit element is an integrated circuit chip, and the carrier element is an interposer.

4. The method according to claim 1, wherein the sloped portion of the sidewall is inclined from a lower portion of the sidewall, which is adjacent to the front side, toward the back side.

5. The method according to claim 1, wherein the sloped portion is inclined to the front side at an angle greater than 30 degree.

6. The method according to claim 1, wherein the sloped portion of the sidewall is formed by a bevel cutting process.

7. The method according to claim 1, wherein the sloped portion of the sidewall is formed by a laser cutting process.

8. The method according to claim 1, wherein the sloped portion of the sidewall is formed by a polishing process.

9. The method according to claim 1, wherein the sloped portion of the sidewall is formed by a plasma cutting process.

10. The method according to claim 1, wherein the sloped portion of the sidewall is formed by a waterjet cutting process.

11. A package structure comprising:
a circuit element having a front side, a back side, and at least a sidewall formed between the front side and the back side;
a carrier element attached thereon the circuit element, wherein the front side of the circuit element faces the carrier element; and
an underfill structure disposed between the circuit element and the carrier element, wherein
the circuit element is surrounded by the underfill structure on at least a portion of the sidewall, and the sidewall includes a sloped portion inclined from the front side to the back side at an angle greater than zero degree.

12. The circuit element package structure according to claim 11, wherein the circuit element is an integrated circuit chip, and the carrier element is a substrate.

13. The circuit element package structure according to claim 11, wherein the circuit element is an integrated circuit chip, and the carrier element is an interposer.

14. The circuit element package structure according to claim 11, wherein the circuit element and the carrier element are connected through at least a through silicon via.

15. The circuit element package structure according to claim 11, wherein the sloped portion of the sidewall is inclined from a lower portion of the sidewall, which is adjacent to the front side, toward the back side.

16. The circuit element package structure according to claim 11, wherein the sloped portion is inclined at an angle greater than 30 degree.

17. The circuit element package structure according to claim 11, wherein the circuit element further includes a plurality of bumps disposed on the front side.

18. The circuit element package structure according to claim 17, wherein the bumps are solder balls.

19. The circuit element package structure according to claim 11, wherein the bumps are copper pillars with solders.
